(19) United States
(12) Patent Application Publication
(10) Pub. No.: US 2017/0211743 A1
(43) Pub. Date: Jul. 27, 2017

(54) Rear-Mounted Electronic Display Component Holder

(71) Applicant: Averry Shane YANYK, Calgary (CA)

(72) Inventor: Averry Shane YANYK, Calgary (CA)

(21) Appl. No.: 15/004,336

(22) Filed: Jan. 22, 2016

(51) Int. Cl. F16M 13/02; F16M 11/20; H05K 5/00; A47B 97/00

(52) U.S. Cl. CPC F16M 13/02; F16M 13/027; A47B 97/001; F16M 11/2007; H05K 5/0017; A47B 2097/005; A47B 2097/003

(57) ABSTRACT

A U-shaped component holder for mounting directly on the back of an electronic display, either wall-mounted, ceiling-mounted or free standing, and which does not require special mounting equipment. The component holder is positioned behind the display to maintain components, wires or cables out of sight of viewers of the display. The component holder may be mounted on a variety of VESA standard displays or non-standard display, and may be moved between displays easily and quickly.

### FIELD OF THE INVENTION

The present invention relates to electronic equipment accessories. In particular, the present invention relates to devices for holding electronic components, wires and cables.

### BACKGROUND OF THE INVENTION

It is known in the prior art to provide various devices which permit the storage of electronics components, wiring, and cables in proximity to a television set, computer monitor, or other electronic display.

Such prior art devices generally comprise one or more shelves or devices mounted to the wall or other display mounting surface, or an added surface above or below the display. In some cases, cables are run from the display along the floor, wall or ceiling into a separate room where the components are housed.

In other prior art devices, special tools are required to mount a component holder to a wall, requiring measurement taking, location of structural wall supports, and significant installation time and effort.

Many of these prior art approaches result in components, wiring and cables remaining visible beyond the perimeter of the display. In many cases, prior art approaches to component storage create a display viewing area which is not esthetically pleasing, and which may present safety hazards to customers and children.

In some prior art component holders, the holders form part of the wall mounting apparatus, which does not easily permit transfer of component holders between displays in the event of an equipment upgrade or transfer of the holder to another display.

The spacing of wall mount fasteners on a wall mount for mounting flat panel display, and the corresponding openings in the back of a display, are standardized by the Video Electronics Standards Association (“VESA”). It is desirable to provide a component holder which may be used with a variety of VESA mounts or other standards mounts.

It is desirable, also, to provide a component holder for televisions, computer monitors, and other electronic displays which is easy and quick to install, which adapts to a wide variety of displays, and which is not visible to viewers in the ordinary use of the display.

The device of the present invention addresses the shortcomings in the prior art by providing an improved component holder which connects directly to the back of an electronic display and which contains all components, wiring, and cables out of view of the users of the display.

### BRIEF DESCRIPTION OF THE DRAWINGS

A detailed description of the preferred embodiments of the invention is provided by way of example only and with reference to the following drawings, in which:

FIG. 1 is a rear plan view of a first embodiment of the component holder of the present invention having pairs of lateral openings vertically spaced along both the left and right sides;

FIG. 2 is an isometric view of the first embodiment of the component holder of the present invention depicted in FIG. 1;

FIG. 3 is a rear plan view of a second embodiment of the component holder of the present invention having pairs of lateral openings vertically spaced along only the left side;

FIG. 4 is an isometric view of the second embodiment of the component holder of the present invention depicted in FIG. 3;

FIG. 5 is a rear plan view of a third embodiment of the component holder of the present invention having pairs of internal openings vertically spaced along the left side, the internal openings intersected by a perpendicular vertical channel;

FIG. 6 is a rear plan view of a fourth embodiment of the component holder of the present invention having groups of triangular internal openings spaced vertically along both left and right sides; and

FIG. 7 is an isometric view of the second embodiment of the component holder of the present invention mounted on the back of a wall mounted display.

In the drawings, several embodiments of the invention are illustrated by way of example. It is to be expressly understood that the description and drawings are only for the purpose of illustration and as an aid to understanding, and are not intended as a definition of the limits of the invention.

### SUMMARY OF THE INVENTION

The invention includes a component holder for an electronic display, the component holder comprising a U-shaped bracket having parallel planar front and rear vertical plates connected along adjacent lower edges by a horizontal bottom plate, the component holder further comprising one or more openings through the front plate for passage therethrough of fastening means. The fastening means may be selected from the group of fastening means comprising bolts, screws, and hook and loop fasteners. The fastening means may be a wall mount or ceiling mount apparatus having a wall mount plate and at least two adjacent fasteners for connecting the wall mount plate to the back of an electronic display.

The one or more openings may be a vertical channel and at least one pair of vertically aligned horizontal channels perpendicular to the vertical channel. The at least one pair of horizontal channels may be vertically spaced apart one or more distances selected from the group of distances comprising 75 mm, 100 mm, 200 mm, and 400 mm.

The one or more openings may be one or more pairs of vertically spaced lateral openings along at least one edge of the front plate. The one or more pairs of lateral openings may be vertically spaced apart one or more distances selected from the group of distances comprising 75 mm, 100 mm, 200 mm, and 400 mm.

The invention includes an electronic display assembly comprising an electronic display, a wall mount apparatus connected to the back of the display with fastening means, and a U-shaped component holder mounted to the back of the electronic display using the fastening means of the wall mount apparatus. The component holder may be mounted internal or external to the wall mount apparatus.

The U-shaped component holder may be a bracket having parallel planar front and rear vertical plates connected along adjacent lower edges by a horizontal bottom plate, the component holder further comprising along at least one edge of the front plate a vertical channel and at least one pair of vertically aligned horizontal channels perpendicular to the vertical channel. The horizontal channels are vertically spaced apart one or more distances selected from the group of distances comprising 75 mm, 100 mm, 200 mm, and 400 mm.

The U-shaped component holder may be a bracket having parallel planar front and rear vertical plates connected along adjacent lower edges by a horizontal bottom plate, the component holder further comprising one or more pairs of lateral openings through the front plate for passage therethrough of fastening means. The one or more pairs of lateral openings are vertically spaced apart one or more distances selected from the group of distances comprising 75 mm, 100 mm, 200 mm, and 400 mm.

The invention includes a method of mounting a component holder for a wall-mounted electronic display attached to a wall mount, comprising the steps of loosening two adjacent bolts along one side of the wall mount; placing the component holder between the back of the display and the head of each bolt; sliding the component holder into a desired location within the perimeter of the back of the electronic display; and tightening the adjacent bolts. The component holder may be placed external to the wall mount adjacent the head of each bolt, or internal to the wall mount adjacent the back of the electronic display.

### DETAILED DESCRIPTION OF THE INVENTION

As shown in the drawings, there is provided a component holder 2 for an electronic display 4 which may be installed using the existing wall mount 6 and hardware used to connect the television or other display to the wall mount. The component holder may also be installed directly to the back of a free-standing display using the existing hardware. The component holder is installed directly onto the back of the display and allows all components, wires and cables to be stored out of view of a viewer of the display. While this specification describes use of the component holder for a wall-mounted television, it is to be understood that the component holder may also be used analogously for a ceiling mounted display.

As depicted in the figures, the component holder of the present invention consists of a U-shaped bracket having parallel planar front 8 and rear 10 vertical plates connected along adjacent lower edges by a horizontal bottom plate 12. The front plate of the holder includes one or more openings for insertion of screws or bolts 14 to attach the device to the display and, optionally, to a wall or ceiling mount. The front and rear plate of the component holder may also include one or more openings to provide ventilation for the components in the holder.

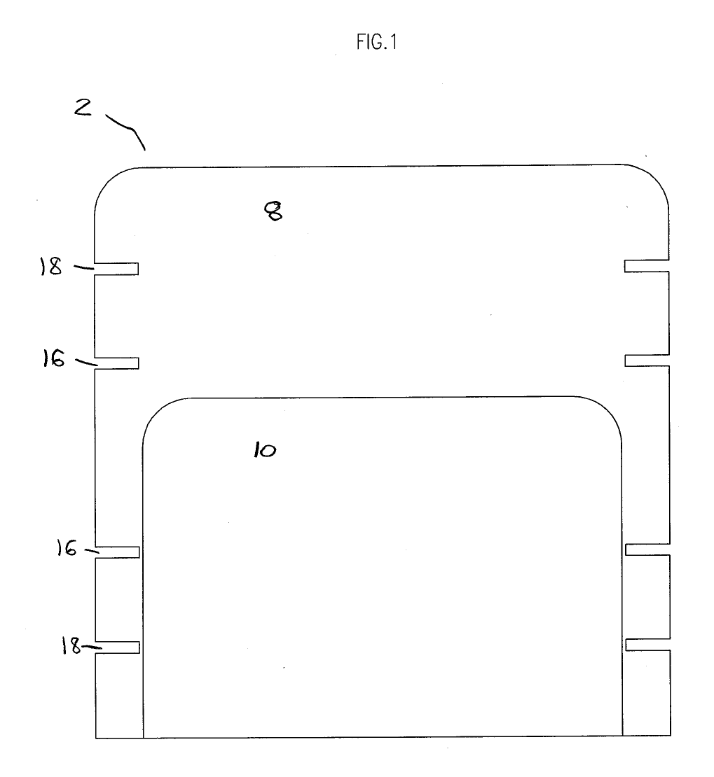

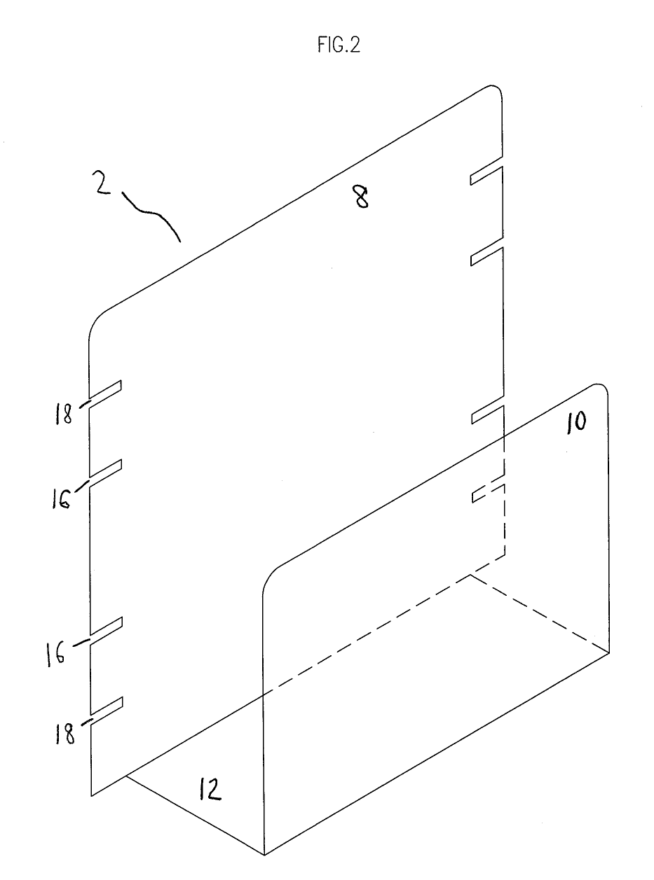

According to one embodiment shown in FIGS. 1 and 2, two pairs of lateral openings 16, 18 spaced 100 mm and 200 mm apart are disposed along each edge of the front plate. For this embodiment, the mounting screws or bolts are loosened sufficiently to permit one edge of the front plate to be slid between the back of the display and either the screw or bolt heads or the wall or ceiling mount hardware. For a wall or ceiling mounted display, the component holder may be inserted internal to the mount or external to the mount.

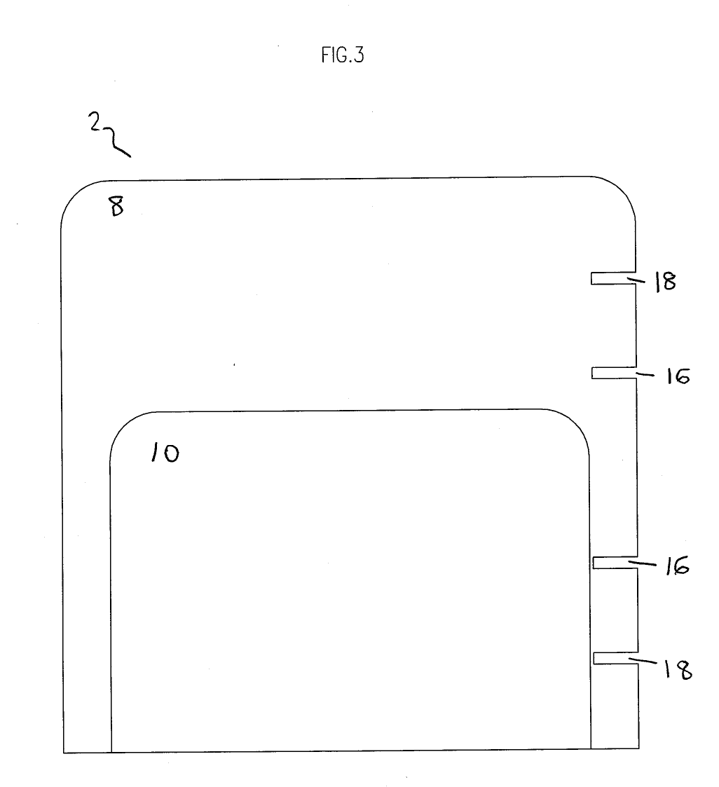

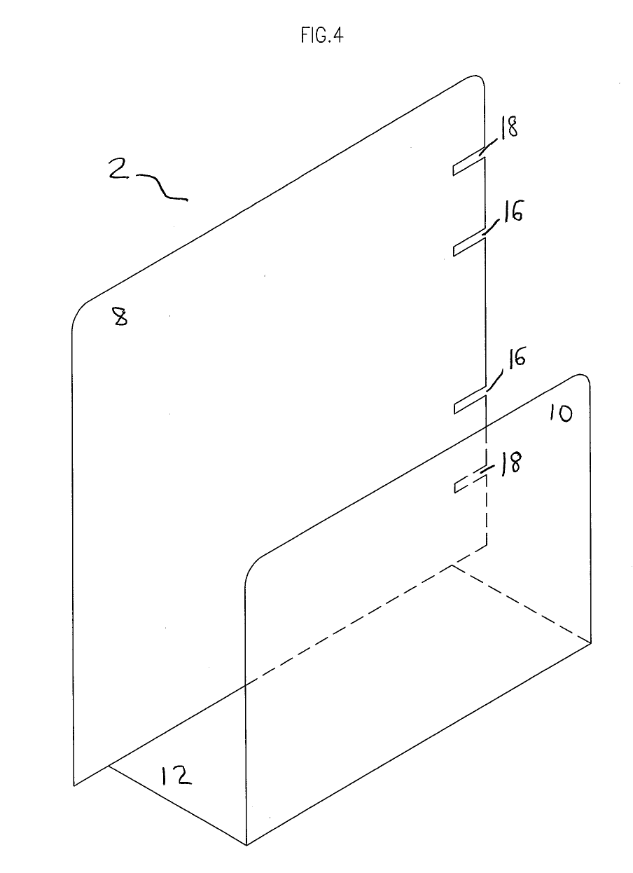

In the embodiment shown in FIGS. 3 and 4, spaced pairs of lateral openings are depicted 100 mm and 200 mm apart along only the left edge of the front plate. The openings may instead be placed only along the right edge. The pairs of spaced openings may also be separated by VESA standard distances of 75 mm or 400 mm, or any other distance corresponding to display mounting systems.

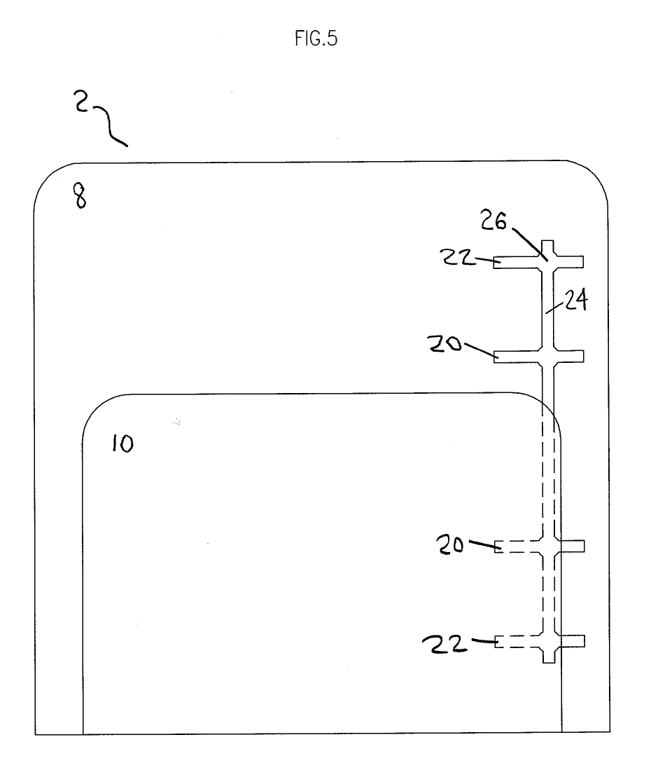

As depicted in FIG. 5, the openings in the front plate may comprise one or more pairs of spaced internal horizontal channels 20, 22 intersecting a vertical channel 24, the branched opening wide enough at the points of intersection 26 of the channels as to permit passage of a head of a screw or bolt, and the channels of a width to prevent passage of the head of the bolt while permitting passage of the bolt shaft, to permit horizontal and vertical adjustment of the component holder position after placement of the holder over the fasteners. The openings in the front plate may be of any shape including, for example, Y-shaped slots. A wide range of adjustments may be achieved through various possible opening shapes or channel pattern designs. While the internal branched channels are depicted only on the left side of the component holder in FIG. 5, the channels may instead be located on the right side only, or on both sides of the front plate.

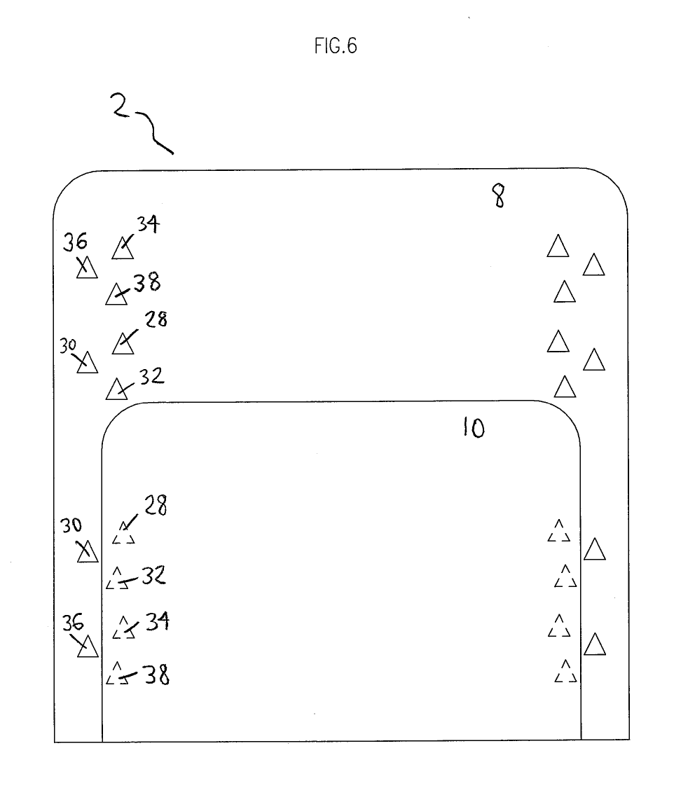

In the embodiment shown in FIG. 6, groups of randomly spaced paired triangular openings are present on the left and right sides of the front plate of the component holder. These openings may instead be placed only one side or the other. In the drawing, three pairs of openings 28, 30, 32 on each side are spaced a VESA standard 100 mm apart, and three pairs of openings 34, 36, 38 are placed a VESA standard 200 mm apart. Other spacing distances are also possible. For this embodiment, the bottom of each triangle is large enough to permit passage over the head of a screw or bolt, while the top of the triangle is narrow enough to permit passage of the shaft but not the head of the screw or bolt. Other opening shapes are possible provided they permit passage of the head of the screw or bolt in only a portion of the opening to allow secure attachment.

In an alternate embodiment in which smaller openings which are large enough to permit passage of the shaft of a screw or bolt but not sufficiently large to permit passage of the head of a screw or bolt, the mounting screws or bolts must be fully removed from the back of the display prior to mounting the component holder.

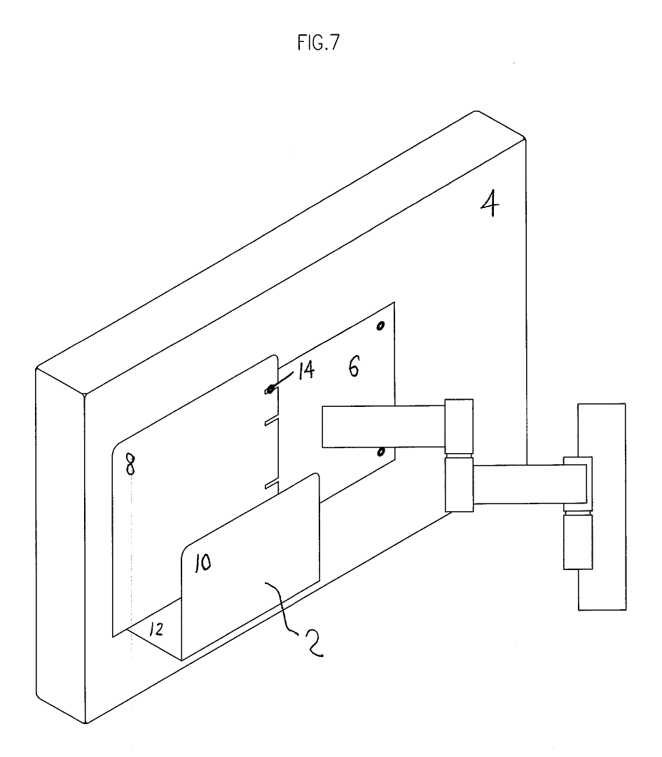

In the embodiment of the component holder for use with a wall-mounted display, as may be seen in FIG. 7, the component holder may be mounted to the back of the display using the existing wall mounting hardware. Two adjacent mounting bolts or screws 14 which attach a wall mounting plate to the back of a display are loosened sufficiently to permit the openings along one side of the component holder to be placed behind the heads of the bolts or screws. The component holder is then slid horizontally to a desired location behind the display, and the mounting bolts or screws are tightened to secure the component holder in place. The component holder is then available for placement therein of electronic components, wires or cables, out of view of the front of the display. In FIG. 7, the component holder is placed external to the wall mount hardware. The component holder may also be placed internal to the wall mount hardware.

The front and rear vertical plates may be of any suitable size which may be accommodated within the cross-sectional area of the left or right side of the back of the display. The front and rear plates may be of differing widths. For example, the front plate may be wider to permit connection to the wall mount without the wall mount projecting into the interior storage space within the component holder. Similarly, the bottom plate may vary in width to accommodate various dimensions of components. According to an alternate embodiment, the bottom plate may be adjustable to permit the front and rear plate to be brought closer together to adjust to the size of the components in the holder. Alternatively, the front plate may be narrower than the rear plate to reduce the amount of material used while allowing storage of components between the rear plate surface and the rear surface of the display. The corners of the front and rear plate may be rounded to reduce the risk of injury posed by a rectangular corner.

The component holder of the present invention permits storage of digital or wireless cable boxes, Wi-Fi routers, satellite receivers, gaming consoles and other electronics components. The presence of a selection of spaced openings on the front plate of the component holder permits use of the component holder with any VESA wall mount hole patterns, including holes spaced apart 100 mm, and 200 mm, as shown in FIGS. 1-4 and 7. Additional opening, spacings and patterns may also be accommodated with various embodiments of the present invention.

The component holder of the present invention eliminates the need for drilling into walls or other mounting surfaces, and the corresponding need to locate wall studs or backing wall structures, does not require measuring or leveling, is simple and quick to install, and does not require special tools. The attachment of the component holder directly on the back of the display eliminates the need to run lengthy wires or cables to the display. By placing the component holder out of sight of the viewers, there is no need to hide components, wires or cables with other objects.

The ability to hide components and cables out of view is very desirable in a component holder system not only in a residential context, but also in an office, restaurant, licensed premises, or other location where esthetics and public safety are valued.

It is to be understood that various sizes of component holder are within the scope of the invention. The shapes and sizes of the vertical and horizontal plates of the component holder may vary, provided the resulting device offers a sturdy base joining two opposing walls and has means for attachment to the back of an electronic display such as a television. Similarly, spaced openings in the front plate of the component holder may be separated by any standard distance consistent with VESA wall mounting standards, other industry standards for wall mounting of displays, or non-standard systems

The dimensions of the openings in the front plate may also vary to accommodate different sizes of screws or bolts, or non-standard mounting hardware. Various materials may be used for the component holder, including metals such as steel or aluminum, plastics, or other durable materials, or any combination of these.

The component holder of the present invention may also be attached to the back of a free standing electronic display such as a desktop computer monitor or a television set mounted on a pedestal.

To secure the components in place in the holder, an anti-slip material may be attached to the upper side of the bottom plate. Securing means such as a hook and loop strap, bungee cord, rubber band, rope or other strap means may be provided to secure the components in place.

It will be appreciated by those skilled in the art that other variations of the preferred embodiment may also be practiced without departing from the scope of the invention.

1. A component holder for an electronic display, the component holder comprising a U-shaped bracket having parallel planar front and rear vertical plates connected along adjacent lower edges by a horizontal bottom plate, the component holder further comprising one or more openings through the front plate for passage therethrough of fastening means.

2. The component holder of claim 1, wherein the fastening means are selected from the group of fastening means comprising bolts, screws, and hook and loop fasteners.

3. The component holder of claim 1, wherein the fastening means comprises a wall mount apparatus having a wall mount plate and at least two adjacent fasteners for connecting the wall mount plate to the back of an electronic display.

4. The component holder of claim 1, wherein the fastening means comprises a ceiling mount apparatus having a ceiling mount plate and at least two adjacent fasteners for connecting the ceiling mount plate to the back of an electronic display.

5. The component holder of claim 1, wherein the one or more openings comprises a vertical channel and at least one pair of vertically aligned horizontal channels perpendicular to the vertical channel.

6. The component holder of claim 5, wherein the at least one pair of horizontal channels are vertically spaced apart one or more distances selected from the group of distances comprising 75 mm, 100 mm, 200 mm, and 400 mm.

7. The component holder of claim 1, wherein the one or more openings comprises one or more pairs of vertically spaced lateral openings along at least one edge of the front plate.

8. The component holder of claim 7, wherein the one or more pairs of lateral openings are vertically spaced apart one or more distances selected from the group of distances comprising 75 mm, 100 mm, 200 mm, and 400 mm.

9. The component holder of claim 1, wherein the horizontal bottom plate is adjustable in width.

10. An electronic display assembly comprising an electronic display, a wall mount apparatus connected to the back of the display with fastening means, and a U-shaped component holder mounted to the back of the electronic display using the fastening means of the wall mount apparatus.

11. The electronic display assembly of claim 10, wherein the component holder is mounted internal to the wall mount apparatus.

12. The electronic display assembly of claim 10, wherein the component holder is mounted external to the wall mount apparatus.

13. The electronic display assembly of claim 10, wherein the U-shaped component holder comprises a bracket having parallel planar front and rear vertical plates connected along adjacent lower edges by a horizontal bottom plate, the component holder further comprising along at least one edge of the front plate a vertical channel and at least one pair of vertically aligned horizontal channels perpendicular to the vertical channel.

14. The wall-mounted electronic display assembly of claim 13, wherein the horizontal channels are vertically spaced apart one or more distances selected from the group of distances comprising 75 mm, 100 mm, 200 mm, and 400 mm.

15. The wall-mounted electronic display assembly of claim 10, wherein the U-shaped component holder comprises a bracket having parallel planar front and rear vertical plates connected along adjacent lower edges by a horizontal bottom plate, the component holder further comprising one or more pairs of lateral openings through the front plate for passage therethrough of fastening means.

16. The wall-mounted electronic display assembly of claim 15, wherein the one or more pairs of lateral openings are vertically spaced apart one or more distances selected from the group of distances comprising 75 mm, 100 mm, 200 mm, and 400 mm.

17. The wall-mounted electronic display assembly of claim 10, wherein the horizontal bottom plate is adjustable in width.

18. A method of mounting a component holder for a wall-mounted electronic display attached to a wall mount, comprising the steps of:
a. loosening two adjacent bolts along one side of the wall mount;
b. placing the component holder between the back of the display and the head of each bolt;
c. sliding the component holder into a desired location within the perimeter of the back of the electronic display; and
d. tightening the adjacent bolts.

19. The method of mounting a component holder for a wall-mounted electronic display of claim 18, wherein the component holder is placed external to the wall mount adjacent the head of each bolt.

20. The method of mounting a component holder for a wall-mounted electronic display of claim 18, wherein the component holder is placed internal to the wall mount adjacent the back of the electronic display.
